(19) United States
(12) Patent Application Publication
(10) Pub. No.: US 2008/0192379 A1
(43) Pub. Date: Aug. 14, 2008

(54) Manufacturing method for magnetic disk drive

(76) Inventors: Masayuki Kurita, Kanagawa (JP); Hideaki Tanaka, Kanagawa (JP); Noriaki Satoh, Kanagawa (JP); Toyomi Ohsawa, Kanagawa (JP); Toshiya Shiramatsu, Kanagawa (JP); Atsushi Yatagai, Kanagawa (JP); Satoshi Ohki, Kanagawa (JP); Hiroshi Ide, Tokyo (JP); Hidekazu Kohira, Kanagawa-ken (JP); Takehiko Hamaguchi, Kanagawa (JP)

Correspondence Address: TOWNSEND AND TOWNSEND AND CREW LLP, TWO EMBARCADERO CENTER, 8TH FLOOR, SAN FRANCISCO, CA, 94111, US

(21) Appl. No.: 12/011,284

(22) Filed: Jan. 24, 2008

(30) Foreign Application Priority Data
Jan. 24, 2007 (JP) 2007-013733

(51) Int. Cl. G11B 5/48; G11B 5/56; G11B 5/60; G11B 21/21; G01R 31/01

(52) U.S. Cl. 360/75; 360/77.04; 29/593

(57) ABSTRACT

Embodiments of the present invention provide a process that monitors a magnetic playback signal while gradually increasing an electricity supply amount for a heater to thereby determine contact between a magnetic head slider and a magnetic disk medium. According to one embodiment, after components for configuring a magnetic recording/playback portion are assembled into a housing, magnetic information is played back on a specific track of a magnetic disk medium by using a playback element while gradually increasing an electricity supply amount for a heater of a magnetic head slider. An amplitude of a playback signal is measured at a plurality of portions along a circumferential direction of the track. Contact between the magnetic head slider and the magnetic disk medium is detected in accordance with an increase in variation in the measured amplitude. Then, a value obtained by subtracting an predetermined value of an electricity amount from an electricity amount in the event of detection of the contact is stored (set) as an appropriate electricity amount for the magnetic head slider into a storage portion.

### CROSS-REFERENCE TO RELATED APPLICATION

The instant nonprovisional patent application claims priority to Japanese Patent Application No. 2007-013733 filed Jan. 24, 2007 and which is incorporated by reference in its entirety herein for all purposes.

### BACKGROUND OF THE INVENTION

In recent years, magnetic disk drives (HDDs) have been widely used not only with computer devices but also with household electric appliance, such as video recorders. Such a magnetic disk drive includes a magnetic disk and a magnetic head slider. While flying over the magnetic disk, the magnetic head slider magnetizes the magnetic disk or reads a magnetized state of the magnetic disk and thereby executes recording to playback of information. For example, in writing information, as the distance between the magnetic disk medium and the magnetic head slider becomes narrower, the expansion of a magnetic field formed by the magnetic head can be reduced to be smaller, whereby the area size to be magnetized on the magnetic disk medium is reduced to be smaller. More specifically, for increasing the record density of the magnetic disk drive, the distance between the magnetic disk medium and the magnetic head, that is, the fly height of the magnetic head slider is sought to be reduced.

As one conventional technique for reducing the fly height of the magnetic head slider, Japanese Patent Publication No. 2005-135501 discloses a technique in which a heater formed from a thin film resistor or the like is mounted in the vicinity of the recording/playback elements. A part of the magnetic head slider is heated and thermally expanded to thereby bring the recording/playback elements to be close to the side of the magnetic disk. In an application of the technique, fly heights of respective magnetic heads are tested and stored during a pre-shipment testing process. Then, in the a product usage event, an amount of heating of the heater is controlled corresponding to any one of appropriate amounts of electricity specific to the magnetic head sliders and usage conditions (such as usage environment temperature, usage environment pressure, zone of a magnetic disk medium targeted for recording/playback, and operation modes such as recording and playback modes).

As described above, the fly heights of the respective magnetic heads have to be tested during pre-shipment testing of the magnetic disk drive. To do this, it is effective to use a method in which the electricity supply amount for the heater is eventually increased, and the phenomenon of contact of the magnetic head slider with the information recording medium is detected and recorded, and the original fly height is inversely calculated from a contact-event amount of electricity and a proportionality coefficient between the amount of electricity and amount of fly height variation.

As a method for detecting contact between the magnetic head slider and the magnetic disk medium, there is a simplest method that does not need the provision of an additional hardware device such as an acoustic emission (AE) sensor, and that detects a vibration from a variation in a magnetic playback signal.

However, substantially no methods have as yet been proposed for calculating the variation in the magnetic playback signal. In addition, in the event that the time interval of sampling of the magnetic playback signal falls just in an integer multiple of a wavelength of a contact vibration, the contact vibration cannot be successfully captured.

### BRIEF SUMMARY OF THE INVENTION

Embodiments of the present invention provide a process that monitors a magnetic playback signal while gradually increasing an electricity supply amount for a heater to thereby determine contact between a magnetic head slider and a magnetic disk medium.

In a manufacturing method for a magnetic disk drive, in which fly heights of magnetic head sliders are respectively regulated have to be set before shipment. According to the particular embodiments disclosed in FIGS. 2 and 4, after components for configuring a magnetic recording/playback portion are assembled into a housing 1, magnetic information is played back on a specific track of a magnetic disk medium 3 by using a playback element 5b while gradually increasing an electricity supply amount for a heater 5c of a magnetic head slider 5. An amplitude of a playback signal is measured at a plurality of portions along a circumferential direction of the track. Contact between the magnetic head slider 5 and the magnetic disk medium 3 is detected in accordance with an increase in variation in the measured amplitude. Then, a value obtained by subtracting an predetermined value of an electricity amount from an electricity amount in the event of detection of the contact is stored (set) as an appropriate electricity amount for the magnetic head slider 5 into a storage portion 15.

### BRIEF DESCRIPTION OF THE DRAWINGS

FIG. 1 is a flow diagram representing a final process of a manufacturing method for a magnetic disk drive in accordance with a first embodiment of the present invention.

FIG. 2 is a block diagram showing an example of the configuration of a magnetic disk drive in accordance with an embodiment of the present invention.

FIG. 3 is a perspective view showing the interior configuration of the magnetic disk drive in accordance with an embodiment of the present invention.

FIG. 4 is a cross sectional view of a peripheral portion of a magnetic head slider of the magnetic disk drive in accordance with an embodiment of the present invention.

FIG. 5 is a cross sectional view of a heater portion of the magnetic head slider as viewed from the side of an air outflow end.

FIG. 6 is a conceptual view showing a calculation method for an index indicative of contact of the magnetic head slider in accordance with the first embodiment.

FIG. 7 is a conceptual view showing a calculation method for the index indicative of contact of the magnetic head slider in accordance with the first embodiment.

FIGS. 8(a)-8(C) are conceptual views for explaining a measuring method for the index indicative of contact of the magnetic head slider in accordance with the first embodiment.

FIG. 9 is a view showing power tables for controlling an electricity amount for a heater in accordance with the first embodiment.

FIG. 10 is a flow diagram representing a final process of a manufacturing method for a magnetic disk drive in accordance with a second embodiment.

FIG. 11 is a conceptual view showing a calculation method for the index indicative of contact of the magnetic head slider in accordance with the second embodiment.

FIG. 12 is a conceptual view showing a determination method for contact of the magnetic head slider in accordance with the second embodiment.

FIG. 13 is a view showing electricity-supply time periods for the heater in amplitude measurement portions of a playback signal in accordance with the first and second embodiments.

### DETAILED DESCRIPTION OF THE INVENTION

Embodiments of the present invention relate to a magnetic disk drive in which a part of a magnetic head slider is heated by heater to control a distance (fly height) from a magnetic disk medium to a magnetic head, thereby to improve recording and playback performances.

Embodiments of the present invention are made in view of the above situations, and an object of certain embodiments is to provide a practical method regarding how to calculate a variation in a magnetic playback signal by using what types of parameters. Further, taking the frequency of contact vibration into account, embodiments of the invention provide a highly reliable contact detecting method that does not fail in detection of a contact state. Further, embodiments of the invention provide a manufacturing method for a magnetic disk drive that sets an appropriate amount of electricity of a respective magnetic head slider by using the aforementioned methods before product shipment.

In order to solve the problems described above, a manufacturing method for a magnetic disk drive in accordance with embodiments of the present invention includes a process that monitors a magnetic playback signal while gradually increasing an electricity supply amount for a heater to thereby determine contact between a magnetic head slider and a magnetic disk medium. An index of contact is set in accordance with an increase in variation within magnetic playback signal amplitude data at a plurality of portions split along a circumferential direction, that is, an increase in spatial variation in the magnetic playback signal amplitude. As a parameter indicative of the magnetic playback signal amplitude, gain of a variable gain amplifier (VGA), for example, can be used.

Preferably, the magnetic playback signal amplitude data in the respective measurement portion is a value obtained by subtracting a value, which has been measured in a state where an electricity supply amount for the heater is sufficiently small and the magnetic head slider and the magnetic disk medium are not in contact with one another, from a value a value measured in the state of electricity supply.

Further, preferably, a distance between each of the plurality of portions for measurement is non-constant or variable, and a minimum alteration unit thereof is smaller than a distance obtained by dividing a peripheral speed of the magnetic disk medium by 300 kHz.

According to embodiments of the present invention, in the manufacturing method for a magnetic disk drive, the appropriate electricity supply amount for the heater of the respective magnetic head slider can be set by detecting contact between the magnetic head slider and the magnetic disk medium from the magnetic playback signal.

A first embodiment of the present invention will be described with reference to drawings.

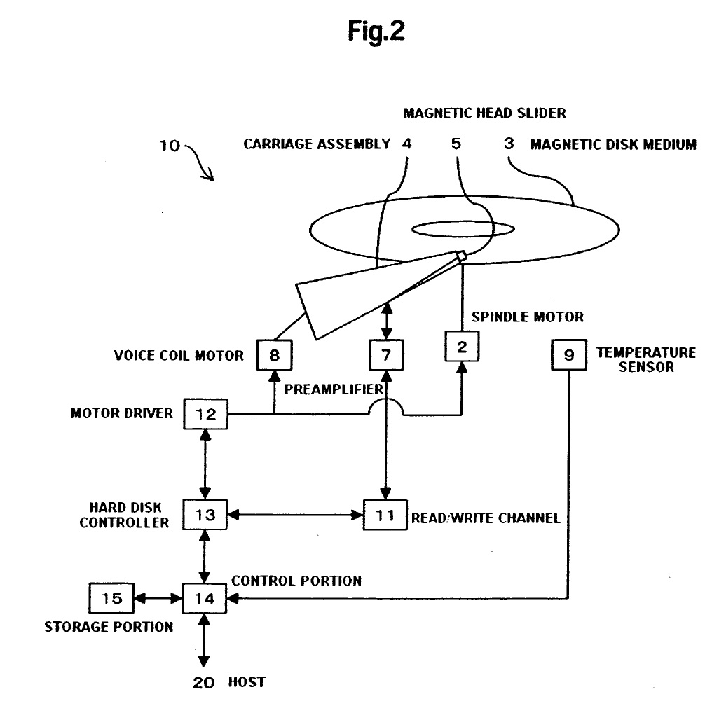

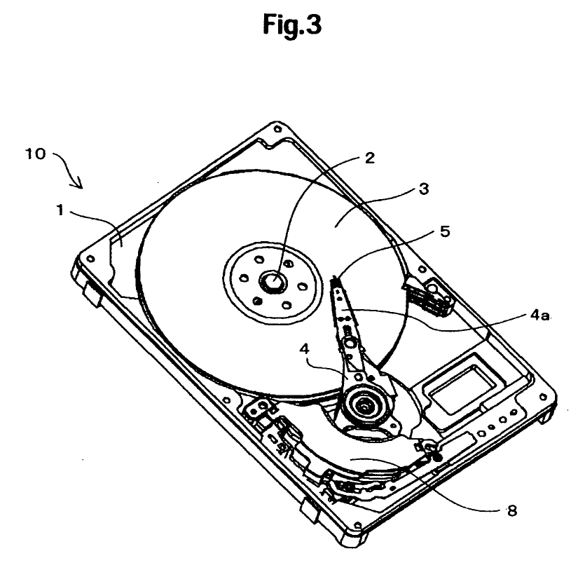

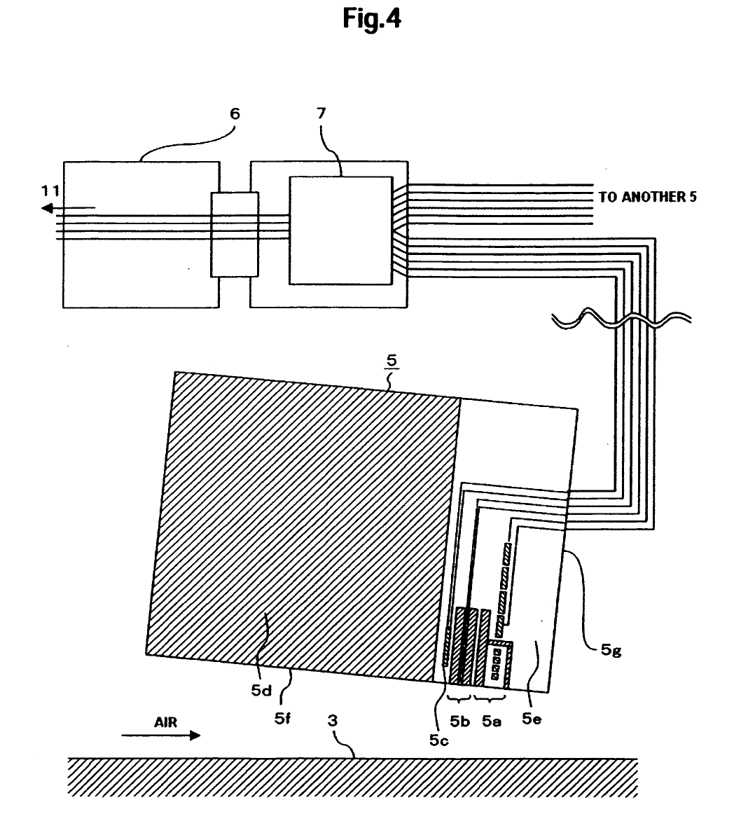

FIG. 2 is a block diagram showing a magnetic disk drive in accordance with the first embodiment of the present invention, FIG. 3 is a perspective view, and FIG. 4 shows a configuration of a magnetic head slider and its peripheral portion. A magnetic disk drive 10 in accordance with this embodiment is configured including a spindle motor 2, a magnetic disk medium 3, a carriage assembly 4, a suspension 4a, a magnetic head slider 5, a preamplifier 7, a voice coil motor 8, a temperature sensor 9, a read/write channel 1, a motor driver 12, a hard disk controller 13 (HDC), a control portion 14, and a storage portion 15, and is built in a housing 1.

The spindle motor 2 rotates one or a plurality of magnetic disk media 3. The carriage assembly 4 is rotated by the voice coil motor 8, thereby to relatively move the magnetic head slider 5, which is attached to a lead end portion of the carriage assembly 4, substantially along a radial direction on the magnetic disk medium 3. With reference to FIG. 4, the magnetic head slider 5 has an air bearing surface, and is lifted on the magnetic disk medium 3 by air pressure. The magnetic head slider 5 includes in its interior a recording element 5a for magnetically recording data onto the magnetic disk medium 3 and a playback element 5b for playing back recorded data. Further, the magnetic head slider 5 includes, in the vicinity of the recording and playback elements, a heater 5c for regulating a distance (fly height) between the recording/playback elements and the magnetic disk medium by utilizing thermal expansion.

Upon receipt of an input signal indicative of record information, the preamplifier 7 amplifies and supplies the signal to the recording element 5a of the magnetic head slider 5. Further, the preamplifier 7 amplifies and outputs a playback signal output from the playback element 5b. Further, upon receipt of an input of a specification of an amount of current for output to the heater 5c, the preamplifier 7 supplies the specified amount of current (or voltage or power) to the heater 5c.

In a midway of a path electrically connecting together the magnetic head slider 5 and the read/write channel 11, there is a provided a “flexible printed cable” 6 (FPC) formed of a flexible wireline that absorbs the rotational motion by the voice coil motor 8 as deflection. The preamplifier 7 is attached onto the FPC 6 in a manner such as soldering.

The temperature sensor 9 detects an environmental temperature in the vicinity the magnetic head slider 5, and outputs a signal indicative of the detected temperature. The temperature sensor 9 may be disposed on the FPC 6, for example. Alternatively, similarly as the HDC 13 and the control portion 14, the temperature sensor 9 may be disposed on a base board (card). The base board (card) is mounted to a reverse face of the housing 1 shown in FIG. 3.

The read/write channel 11 outputs to the preamplifier 7 a signal formed by code modulation of targeted record data. Further, the read/write channel 11 performs code demodulation of a playback signal output from the preamplifier 7, and outputs to the HDC 13 data obtained by the code demodulation.

The motor driver 12 outputs a driving current to, for example, the spindle motor 2 or the voice coil motor 8 in accordance with a specification input from the control portion 14, thereby to operate the spindle motor 2 or the voice coil motor 8.

The HDC 13 receives, for example, record data or command transferred from an external host 20, or transfers playback data output from the read/write channel 11 to the host 20.

The control portion 14 controls a respective portion, such as control of the motor driver 12, to perform position control of the magnetic head slider 5. The control portion 14 is a program control device, such as a microcomputer, and operates in accordance with self-contained programs and/or programs stored in the storage portion 15. According to the present embodiment, the control portion 14 provides to the preamplifier 7 the specification of the amount of current for supply to the heater 5c. Operation information and the like information of the control portion 14 will be described below.

The storage portion 15 contains, for example, programs for execution by the control portion 14 and data necessary for execution of the programs. The storage portion 15 further contains values (control parameters corresponding to electricity supply amount for the heater 5c) that the control portion 14 references when controlling the heater 5c and sets into heater control registers of the heater 5c. Examples of the control parameters will be described below. The storage portion 15 is a nonvolatile memory, such as an EEPROM (electrically erasable programmable read only memory). Depending on the case, the storage portion 15 may further include a partial area of the magnetic disk medium 3. In this case, in manufacture, the control parameters are stored in the magnetic disk medium 3; and in use, after power-on the control parameters are first copied into a memory accessible at high speed from the magnetic disk medium 3, and are then referenced in control of the heater 5c.

A general forming process for the magnetic head slider 5 will be described hereinbelow. To begin with, large numbers of, for example, heaters 5c, playback elements 5b, recording elements 5a, and wirelines connecting thereto are laminated by a thin-film process on a wafer 5d of an alumina-titanium-carbide sintered compact (“AlTiC,” hereinbelow). The heaters 5c are disposed between the AlTiC portion 5d and the playback elements 5b. Then, the structure in the wafer state is cut and separated by dicing into a bar state, and is further cut and separated into discrete sliders. Before or after the process, an air bearing surface 5f in the bar or slider state is polished to be smooth, thereby to form a carbon protection film. Further, a step bearing in a shape for effectively generating air pressure is formed on the air bearing surface 5f.

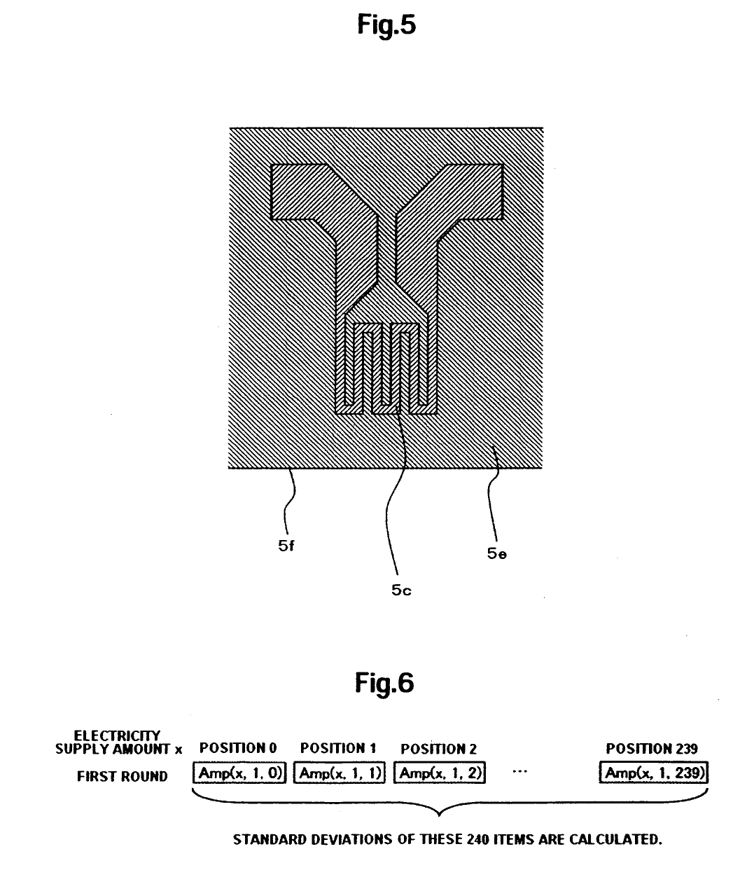

FIG. 5 shows a cross sectional view of a layer of the heater 5c as viewed from the side of an air outflow end face 5g. A material of the heater 5c is an electrically conductive thin film of a material such as a nickel-chrome alloy, having a relatively high resistance value. After a uniform film is formed by sputtering or the like manner, an unnecessary portion is removed by milling or the like manner, whereby a profile as shown in FIG. 5 is formed. The removed portion is covered by an insulation film 5e of, for example, alumina. In the present embodiment shown in FIG. 4, the heater 5c is disposed between the AlTiC portion 5d and the playback element 5b; however, the heater 5c may be in a different portion as long as the fly height of the recording/playback elements portion can be effectively controlled by utilizing thermal expansion. For example, the heater 5c may be disposed between the recording element 5a and the playback element 5b. A resistance value of, for example, 100Ω, can be realized if appropriate design is carried out for the thickness of the electrically conductive film and the ratio between the length and width of a thin line of a meandering portion.

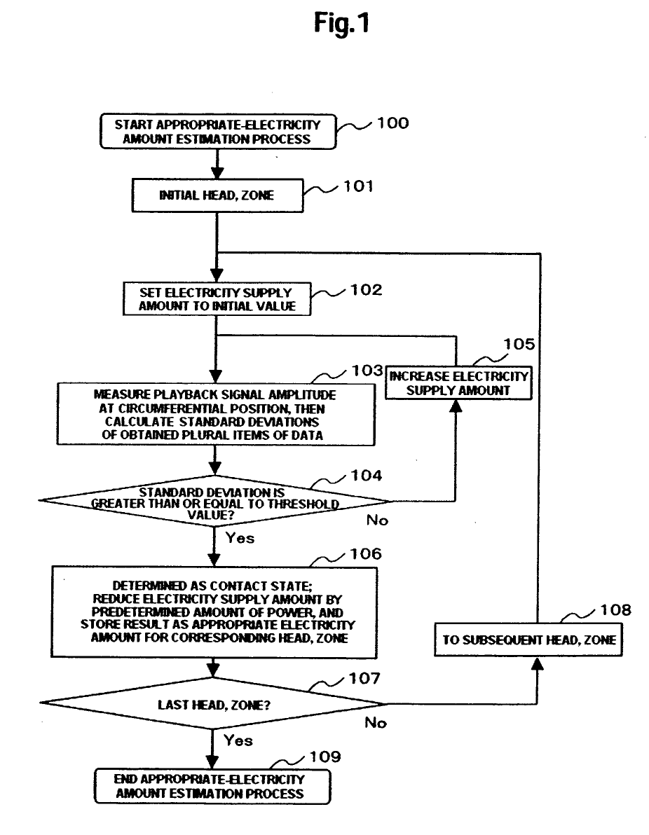

FIG. 1 is a flow diagram representing a manufacturing method for the magnetic disk drive in accordance with the first embodiment of the present invention. More specifically, the diagram represents a final process after respective components of the magnetic disk drive is mounted in the housing 1 shown in FIG. 3. As described in the Related Art section, it is necessary that, before the pre-shipment testing process or the final process of the manufacture of the magnetic disk drive, the fly heights of the respective heaters 5c are tested, and appropriate electricity supply amount for the heaters 5c are estimated and stored (set) in the storage portion 15.

Upon start of an appropriate electricity estimation process (step 100), a first one of the plurality of magnetic head sliders 5 is positioned on a specific track of specific zone of the magnetic disk medium 3 (step 101). At the outset, the electricity supply amount for the heater 5c is set to an initial value (step 102). The initial value is a value at which the magnetic head slider 5 and the magnetic disk medium 3 do not contact with one another, and the electricity amount is zero (0). Subsequently, at steps 103 to 106, the electricity supply amount for the heater 5c is gradually increased, in which a phenomenon in which the magnetic head slider 5 vibrates upon contact with the magnetic disk medium 3 is detected from a variation in the magnetic playback signal.

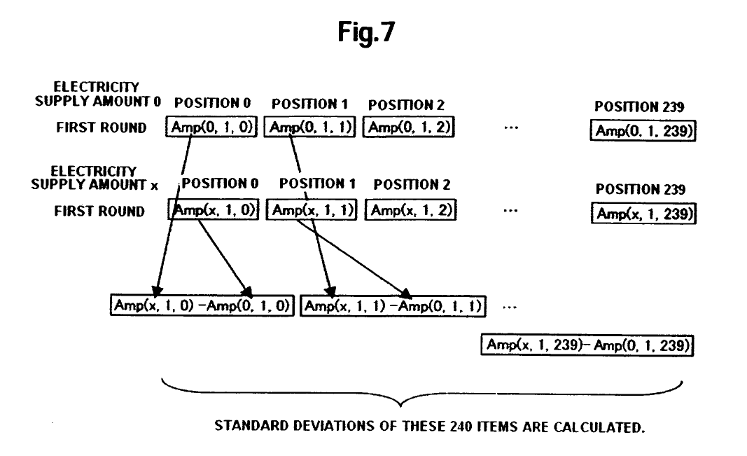

When the magnetic head slider 5 vibrates upon contact with the magnetic disk medium 3, the distance from the playback element 5b to the magnetic disk medium 3 increases and decreases in operative association with the vibration. As a result, the amplitude (intensity) of the magnetic playback signal varies. In this case, the magnetic signal should be recorded in a state the magnetic head slider 5 and the magnetic disk medium 3 are not in contact with one another. As shown in FIG. 6, in the present embodiment, the amplitudes of the magnetic playback signal are measured at a plurality of positions (240 portions per disk revolution, for example), and standard deviations of plural items of data thus obtained are calculated. With reference to FIG. 6, in Amp (X, 1, 0), X represents the electricity supply amount for the heater 5c, 1 represents an initial cycle of measurement, and 0 represents a disk circumferential position (sector). With reference to FIG. 7, in order to remove an initial variation, amplitudes of the magnetic playback signal corresponding to an initial electricity amount (“initial” herein refers to a state where the electricity supply amount for the heater is sufficiently small, and the magnetic head slider and the magnetic disk medium are not in contact with one another) is subtracted from a respective amplitude of the magnetic playback signal corresponding to the electricity amount. Then, standard deviations of plural items of data thus obtained are calculated. Thus, an index of contact is represented by an increase in spatial variation in the magnetic playback signal amplitude.

The value of the magnetic playback signal amplitude after contact varies greater than that before contact, so that the standard deviation corresponding to the items of data significantly increases. First, a value obtained by performing a multiplication of the standard deviation by a fixed multiplication factor, such as 3 (times) or 5 (times), of a standard deviation in an obvious noncontact state is set as a threshold value. Then, the electricity supply amount for the heater 5c is gradually increased, in which a state where the standard deviation corresponding to the items of data has exceeded the threshold value, the state is determined to be a contact state. Even when contact is not caused, when the magnetic head slider 5 approaches the disk medium 3 thereby to cause an increase of the value itself (average value) of the playback signal amplitude, also the standard deviation naturally increases. In order to accurately detect only the increase of the standard deviation caused by the contact vibration, the standard deviation can be calculated after being normalized by the average value. By execution of the above-described process, an electricity amount for initiating contact between the head and the zone in the playback mode under conditions (a normal pressure and a room temperature) for performing the pre-shipment testing can be known.

The process described above is executed for respective one of all the magnetic head sliders on one or a plurality of radial zones (steps 107 to 109). It is possible that the appropriate-electricity amount estimation process is executed on only one zone on the outer circumference, but compensation is provided on the other zone by a typical radial fly variation profile obtained by, for example, fly height modeling or sample testing. However, it is desirable that the appropriate-electricity amount estimation process be carried out on, for example, three, outer, inbetween, and inner circumferential zones. Of course, when an even more accurate appropriate electricity amount estimation process data on respective one of a larger number of zones, such as 30 zones, for example, even more accurate appropriate electricity amount data can be obtained. However, when head damage due to contact is taken into account, about three portions are most appropriate.

In the process described above, as a parameter indicative of the amplitude of the playback signal, a gain regulation parameter (gain of variable gain amplifier (“VGA,” hereinbelow)), for example, is used. The preamplifier 7 amplifies a playback signal played back by the playback element 5b, and sends the amplified playback signal to the read/write channel 11. The read/write channel 11 amplifies the playback signal, which has been sent from the preamplifier 7, to a constant or fixed amplitude, extracts data from the received playback signal, and provides a decoding process thereon. A parameter used for the amplification is the gain of VGA. As the gain of VGA is larger, the source signal is less intense—which is indicative that the distance between the playback element 5b and the magnetic disk medium 3 (i.e., the fly height of the playback element 5b) is large. In contrast, as the gain of VGA is smaller, the source signal is more intense—which is indicative that the distance between the playback element 5b and the magnetic disk medium 3 is small.

The gain of VGA includes two types, namely, a gain for servo VGA (servo VGA gain) for servo data and a gain for data VGA (data VGA gain) for user data. Servo data fields include not only fields, such as a field storing servo sector numbers (servo IDs) and a field storing position error signals (PES), but also a field storing signals called as preamble signals. Preamble signals are recorded as signals having a fixed frequency and uniform in terms of the radial direction for attaining frequency synchronism. The servo VGA gain is a parameter that is calculated by the read/write channel 11 from an amplitude with which the preamble signal has been read out.

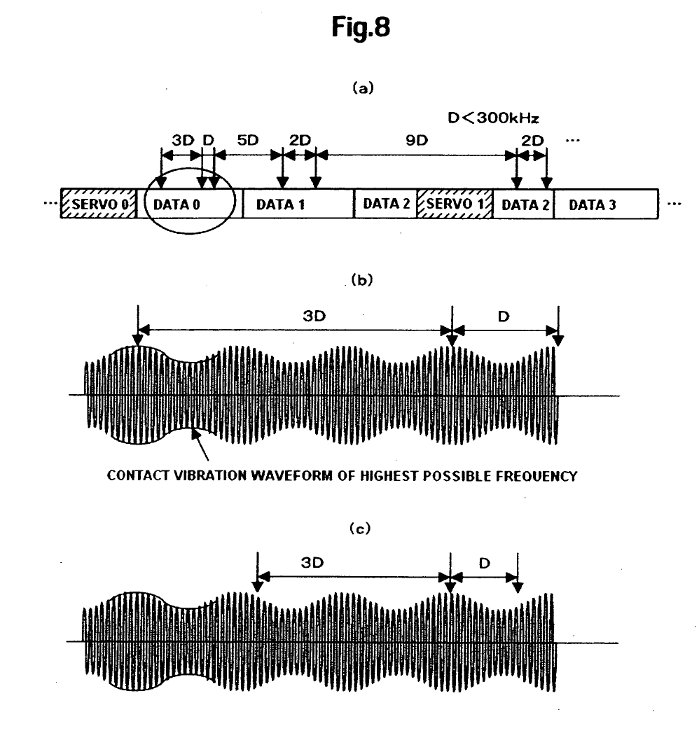

The data VGA gain is a parameter to be calculated by the read/write channel 11 from a playback signal amplitude of data, which has a constant frequency and which is preliminarily recorded, in order to make a gain for reading user data to be constant. As such, before measuring of the data VGA gain, single-frequency signals similar to preamble signals but different from innate user data have to be preliminarily recorded the data sector (not only in a sync portion but in the whole). FIG. 8(a) shows servo data fields in a servo sector, user data fields, and spacing distances D, 2D, 3D, 5D, and 9D for sampling of playback signal amplitudes. A minimum alteration unit of the spacing distance is D.

Using any one of the two types, i.e., servo VGA gain and data VGA gain, enables effects of embodiments of the present invention to be obtained. The servo VGA gain has an advantage of enabling measurement not only during playback operation but also during recording operation. However, utilizing the data VGA gain enables provision of technical measures for successful detection or capture of contact vibrations.

FIGS. 8(b) and 8(c), respectively, are conceptual views representing a situation in which contact vibrations are occurring in the event magnetic data stored at a constant amplitude and a single frequency. However, small vibration waveforms are shown by being enlarged along the horizontal axis (time axis) to be larger than those actually formed. The frequency of actual record data is in the range of from several tens to several hundreds of kilohertz (KHz), the small vibration waveforms as shown in FIGS. 8(b) and 8(c) are actually smaller, such that they are not supposed visible unlike those shown in the drawing views in such a fashion as separated from one another.

With reference to FIG. 8(b), the spacing distance D, 3D for sampling the playback signal amplitude by using the data VGA gain is just an integer multiple of the contact vibration wavelength, the contact vibration cannot be successfully detected. In the present case, while sampling is done at unequal distances, even in the event of sampling at the equal distances, when the sampling distances are each an integer multiple of the contact vibration wavelength, the contact vibration cannot be successfully detected.

In FIG. 8(c), the spacing distances D and 3D are for sampling at an unequal distance having a constant pattern or sampling at a random, unequal distance, and the minimum alteration unit D of the distance is smaller than the wavelength of a possible contact vibration wavelength. In this case, the frequency is not synchronized with the contact vibration, so that variations in gain of VGA due to the contact vibration can be successfully detected.

While the frequency of contact vibration varies corresponding to the vibration mode, the frequency of a pitch direction vibration of the magnetic head slider 5 is highest as being ranged from some latter half of 100 KHz to some 200 kHz. The frequency of a sway direction vibration along an in-plane direction from a base of the suspension 4a that supports the magnetic head slider 5 and exerts a force of pressing it onto the magnetic disk medium 3 is lower than the frequency of pitch direction vibration. A smallest one of contact vibration wavelengths corresponds to a distance obtained by dividing the peripheral speed of the magnetic disk medium by 300 kHz. As such, the distances along a plurality of portions for measuring the amplitudes of the playback signal are non-constant or variable, and the minimum alteration unit D is smaller than a distance obtained by dividing the peripheral speed of the magnetic disk medium by 300 kHz.

As described above, according to the first embodiment, in the final step of the manufacture of the magnetic disk drive, the appropriate amount of electricity can be determined and set by detecting contact of the magnetic head slider from the variation in the magnetic playback signal. In this case, the contact state can be securely detected by taking the frequency of contact vibration of the magnetic head slider into account.

In addition to the above-described contact detection method using variation in the playback signal amplitude, a contact detection method different from the above-described method may be additionally used. For example, when the electricity supply amount for the heater 5c is gradually increased, the playback signal amplitude is substantially linearly increased as the distance between the playback element 5b and the magnetic disk medium 3; however, after start of contact, variation in the playback signal amplitude deviates from the linear transition. The contact detection method may be based on the phenomenon. However, in many cases, such a phenomenon of deviation of variation in the playback signal amplitude is detected after passage through a true contact point (inflection point), and is detectable later than in the “contact detection (method) using the playback signal amplitude variation” described in the embodiment described above. As such, instead of total replacement of “contact detection (method) using the playback signal amplitude variation” according to the embodiment described above, it can be additionally used as a backup.

In addition, a method is available that measures an off-track component of contact vibration by monitoring position error signals (PES). While the method has a problem in that sensitivity is different depending on the radial position and is low on an inbetween circumference portion, the method can be used as a backup of the “contact detection (method) using the playback signal amplitude variation.”

The electricity supply amount for the heater 5c, which regulates the fly height, is regulated corresponding to the operating head, zone, operating temperature, or operating mode. More specifically, taking fly height variation into account, the step bearing is designed so that, even when there are added other overlapping low fly conditions, such as operating temperature and mode, at a lowest air pressure corresponding to a highest latitude predetermined as a specification, the magnetic head slider 5 does not contact with the magnetic disk medium 3.

Compensation for fly height variance of the discrete or respective head slider will be described hereinbelow. The fly height is different depending on the respective head slider. In a pre-shipment testing process, when contact detection is carried out by gradually increasing the heater-actuating electricity supply amount on a zone or respective zone, a respective distance (clearance) leading to contact of the respective head slider can be obtained. In the product, values each obtained by subtraction of a reliability margin from the heater-actuating electricity supply amount leading to contact are preliminarily recorded in the storage portion 15 in units the respective head slider. Upon receipt of a pre-recording/playback seek command seek command from the host 20, a value in the heater control register of the preamplifier 7 is appropriately updated in accordance with recording/playback head number information.

Another method is available in which the clearance respective head slider is not obtained by the contact detection. According to the method, a recording/playback performance examination is carried out for an error rate or the like by eventually increasing the heater-actuating electricity supply amount in a zone or respective zone in a pre-shipment testing process, and an amount of electricity in the event a desired value is reached is adopted as a specific amount of electricity for the corresponding head slider. In this case, a process called “clearance checking process” needs to be performed. In this process, a value obtained by adding an electricity amount corresponding to the reliability margin to the electricity amount determined in the above-described method is actually applied, thereby to verify that contact dose not occur.

Compensation for fly height variance associated with a zone of the magnetic disk medium will be described hereinbelow. The fly height is different depending on the zone. As a profile thereof, an average profile of the zones can be known through design values or sample tests carried out in a laboratory. Alternatively, in the pre-shipment testing process, the respective profile corresponding to the respective head slider can be obtained through contact detection carried out by gradually increasing the appropriate heater-actuating electricity supply amount corresponding to the respective zone. In the product, per-zone appropriate heater-actuating electricity supply amounts are preliminarily recorded in the form of tables in the storage portion 15. Upon receipt a seek command from the host 20, the value in the heater control register of the preamplifier 7 is appropriately updated in accordance with recording/playback zone information.

A method for storing control parameters by splitting the magnetic disk medium 3 into a large number of zones is most accurate. However, a method in which common control parameters for the whole of the magnetic disk medium 3 (that is, the number of zones is only one) may be employed. Alternatively, control may be provided in the manner that control parameters are stored by being separated into a small number of zones, such as three zones corresponding to an outer, inbetween, and inner circumferential portions, in which ranges thereamong may be controlled by being interpolated through, for example, a primary or secondary expression.

Compensation for fly height variance associated with the environmental temperature will be described hereinbelow. When the environmental temperature is high, the fly height is reduced due to the effects of thermal protrusion caused due to a difference between the linear expansion coefficients of the recording/playback elements material and the peripheral material. In contrast, when the environmental temperature is low, the fly height is increased. According to embodiments of the present invention, in the product, an appropriate heater-actuating electricity supply amount(s) corresponding to an environmental temperature zone(s) is recorded as a single numeric value (coefficient) or a plurality of numeric values (table) in the storage portion 15. The respective value is obtained in accordance with the result of preliminarily investigation of effects of the environmental temperature on the fly height in a laboratory. When a seek command is received from the host 20, the value in a heater control register of the preamplifier 7 is appropriately updated in accordance with information received from the temperature sensor 9.

Control may be provided in the manner that a range between upper and lower limits of operation guaranteeing temperatures is split into a large number of temperature zones, and all control parameters corresponding to the respective temperature zones are stored. Alternatively, control may be provided in the manner that only control parameters corresponding to a limited number of temperature zones, such as three temperature zones corresponding to a low, normal, and high temperatures are stored, in which ranges thereamong are interpolated through, for example, a primary or secondary expression.

Compensation for fly height variance associated with an operation mode, such as mode of record or playback operation, will be described hereinbelow. Recording current in the recording operation works similar to heater current to thereby cause thermal expansion deflection, such that the fly height during the record operation is reduced relative to that in the playback operation. The amount of reduction (amount of fly variation associated with write protrusion) can be known through design values or sample tests carried out in a laboratory. Alternatively, in the pre-shipment testing process, the respective amount of fly variation associated with write protrusion corresponding to the respective head slider can be obtained through a comparison between a playback signal wavelength amplitude immediately after consecutive writes and a playback signal wavelength amplitude not associated with write. In the product, heater-actuating electricity supply amounts for compensation of write protrusion are preliminarily recorded in the storage portion 15. Upon receipt of a pre-recording/playback seek command from the host, a value in a heater control register of the preamplifier 7 is appropriately updated in accordance with operation mode information.

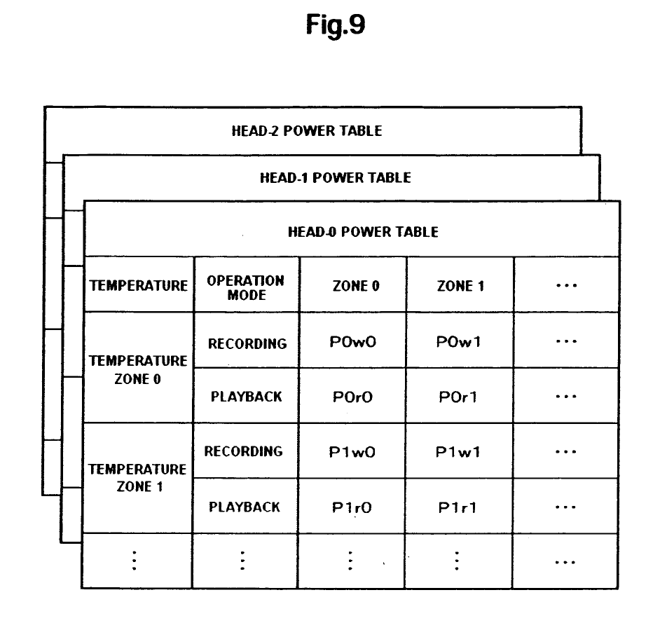

In a summary of the heater-actuating electricity supply amount setting methods described above, electricity amount tables as shown in FIG. 9 are created and stored in the storage portion 15 before shipment. When a pre-recording/playback seek command is received from the host 20, the value in the heater control register is appropriately updated in accordance with any one of the recording/playback head number information, zone information, temperature zone information output from the temperature sensor 9, and operation mode information.

For controlling the heater of the preamplifier 7, three methods, namely, methods for power control, voltage control, and current control are used. The heater-induced fly height variation is substantially proportional to the power, and is proportional to the square of the voltage or current value. As such, the level of heating of the heater is first calculated based on the power. For the power control, a simple addition operation is sufficient. More specifically, the addition operation is carried out to add together amounts of power respectively corresponding to the fly height variances associated with the respective head slider and the zone, the fly height variance associated with the environmental temperature, and the fly height variance associated with the operation mode. Thereby, the total amount of power is calculated. For calculation by using voltage or current values, it is necessary that the sum of squares of the voltage or current value for compensating for the respective single fly height variance, thereby to obtain the total amount of voltage or current.

An example of operation of the magnetic disk drive 10 manufactured as described above will be described herebelow. For description, it is contemplated that values (control parameters) for controlling the amounts of electricity for supply to the heater 5c in the events of recording and playback are preliminarily stored and set in the storage portion 15 in correspondence to the respective heads, temperature zones, and zones.

Upon receipt of a data recording command and recording-targeted data from the host 20, the HDC 13 outputs the recording-targeted data to the read/write channel 11, and outputs to the motor driver 12 a specification for moving the magnetic head slider 5 to a recording position corresponding to the command. In this event, the control portion 14 obtains information of an environmental temperature in accordance with a signal output from the temperature sensor 9. Then, corresponding to a temperature zone of the environmental temperature indicated in the obtained information, the control portion 14 obtains a control parameter (control parameter corresponding to the recording event) stored in the storage portion 15. The control portion 14 outputs to the preamplifier 7 a specification for setting the electricity supply amount for the heater 5c to the above-described specified value. In response, the preamplifier 7 supplies the heater 5c with a current as an electricity amount corresponding to the specified value. Then, the heater 5c heats the vicinity of the recording/playback elements of the magnetic head slider 5.

Concurrently, the read/write channel 11 outputs to the preamplifier 7 a signal formed by modulation of the recording-targeted data, and the preamplifier 7 amplifies and outputs the signal to the recording element 5a of the magnetic head slider 5. Thereby, the recording-targeted data is recorded onto the magnetic disk medium 3.

Similarly, upon receipt of a data playback command and playback data from the host 20, the HDC 13 outputs a playback specification in accordance with the playback command to the read/write channel 11, and outputs to the motor driver 12 a specification for moving the magnetic head slider 5 to a playback position corresponding to the command. In this event, the control portion 14 obtains information of an environmental temperature in accordance with a signal output from the temperature sensor 9. Then, corresponding to a temperature zone of the environmental temperature indicated in the obtained information, the control portion 14 obtains a control parameter (control parameter corresponding to the playback event) stored in the storage portion 15. The control portion 14 then outputs to the preamplifier 7 a specification for setting the electricity supply amount for the heater 5c to the above-described specified value. In response, the preamplifier 7 provides to the heater 5c a current supply as an amount of electricity corresponding to the specified value. Then, the heater 5c heats the vicinity of the recording/playback elements of the magnetic head slider 5.

Concurrently, the preamplifier 7 amplifies and outputs a playback signal output from the playback element 5b of the magnetic head slider 5 to the read/write channel 11. The read/write channel 11 generates playback data by demodulation of the signal amplified by the preamplifier 7, and outputs the playback data to the HDC 13. The HDC 13 outputs the playback data to the host 20.

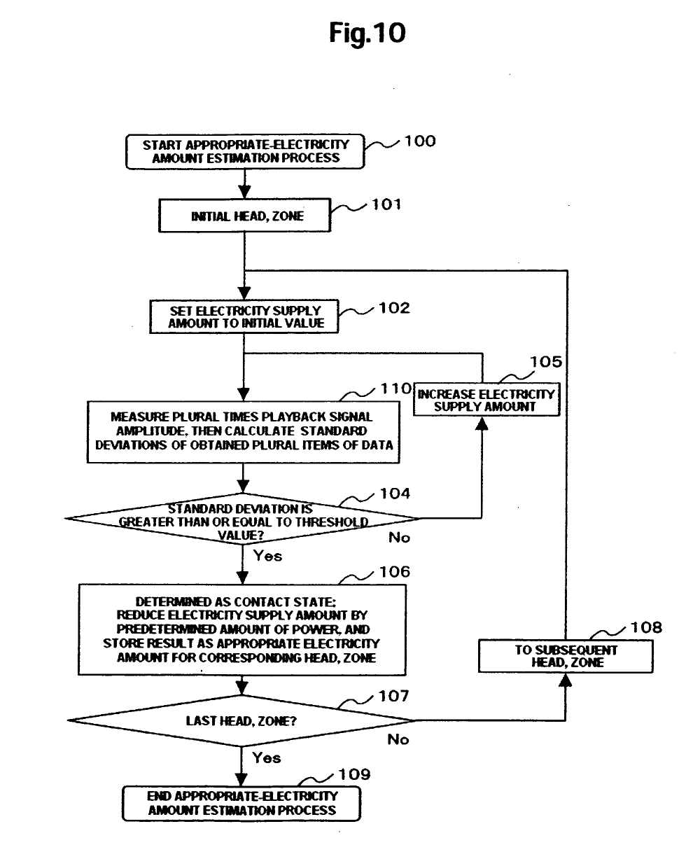

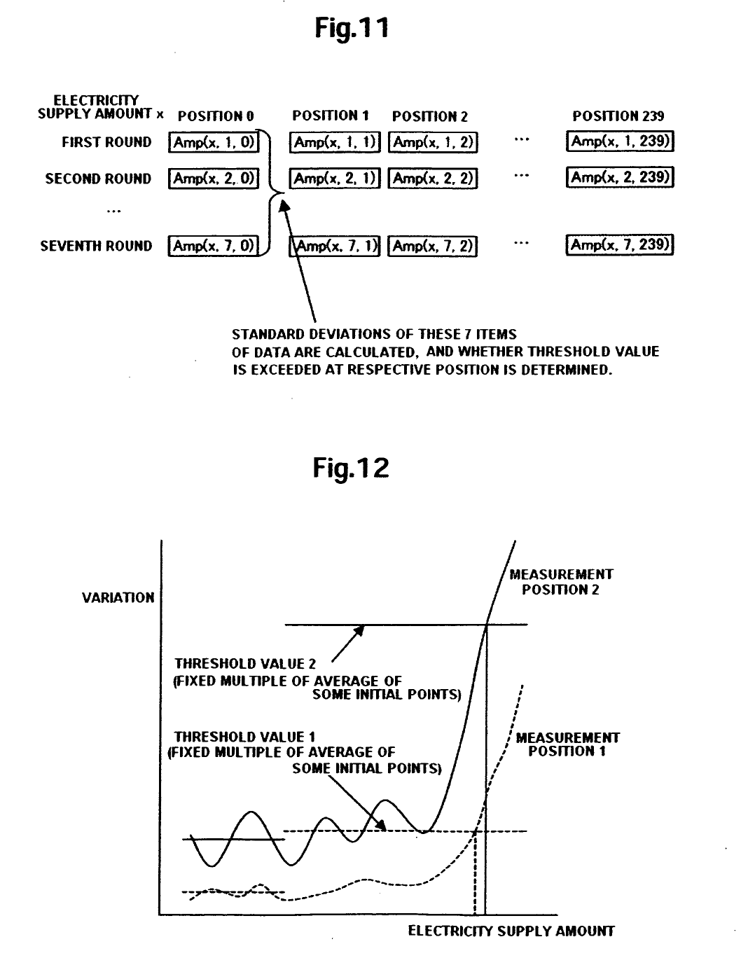

A second embodiment of the present invention will be described hereinbelow with reference to the drawings. FIG. 10 is a flow diagram representing a manufacturing method for a magnetic disk drive in accordance with the second embodiment. A difference from the first embodiment shown in FIG. 1 lies on step 110. In the present embodiment, in lieu of measuring the playback signal amplitudes at the plurality of circumferential positions, the playback signal amplitude is measured plural times (seven times, for example) at the same position, and a standard deviation (variation) of obtained items of data is calculated, as shown in FIG. 11. More specifically, the index of contact is represented by an increase in time variation in the magnetic playback signal amplitude.

The value of the magnetic playback signal amplitude before contact varies greater than in that after contact, so that the standard deviation of the items of data significantly varies. First, a value obtained by performing a multiplication of the standard deviation by a fixed multiplication factor, such as 3 (times) or 5 (times), of a standard deviation in an obvious noncontact state is set as a threshold value. Then, the electricity supply amount for the heater 5c is gradually increased, in which a state where the standard deviation of the items of data has exceeded, the state is determined to be a contact state. As a parameter representing the magnetic playback signal amplitude, either the servo VGA gain or data VGA gain can be used for simplification.

According to the present embodiment, the measurement position can be at only one portion. In consideration of deflection of the magnetic disk medium 3, however, it is desirable that the playback signal amplitude be measured at a plurality of circumferential positions. By way of example, FIG. 11 shows the case of measurement being performed at 240 positions. When the measurement results of circumferential fly height fluctuations are taken into account, about 20 will enable obtaining sufficient sensitivity improvement effects.

As determination manners in the event of measurement at a plurality of circumferential positions, three methods described below are available.

A first method is such that a single threshold value is set, in which, an instance in which an average of standard deviations at a plurality of positions exceeds the threshold value, the instance is determined to be a contact instance. This method is advantageous in that, since the standard deviation in a noncontact instance is small and stable, in an instance where the standard deviation is transiently increased for a causative factor than contact, the risk of making an erroneous determination of the instance to be a contact instance is low. On the other hand, however, the method is disadvantageous in that the sensitivity to the contact is low.

A second method is such that a single threshold value is set, in which, in an instance where a maximum one of standard deviations at a plurality of positions or some percent thereof exceeds the threshold value, the instance is determined to be a contact instance. In contrast to the first method, the second method is advantageous in that the sensitivity to the contact is high, but is, on the other hand, disadvantageous in that, in an instance where the standard deviation is transiently increased for a causative factor other than contact, the risk of making an erroneous determination of the instance to be a contact instance is high.

A third method is such that threshold values are set respectively corresponding to a plurality of positions, in which, in an instance where any one or some percent of standard deviations at a plurality of positions exceeds the respective threshold values, the instance is determined to be a contact instance. The third method is illustrated in FIG. 12. The vertical axis represents a parameter indicative of variation such as standard deviation, and the horizontal axis represents the electricity amount. For respective measurement positions, an average of standard deviations corresponding to some initial points is multiplied by a constant scale factor, such as 3 or 5, whereby the resultant values are set as threshold values for the positions. More specifically, a small threshold value is set for a measurement position 1 where the variation is small by nature, and a large threshold value is set for a measurement position 2 where variation is small by nature. Technical measures as described above prevent the risk that an instance where the standard deviation is transiently increased for a causative factor other than contact at a position where variation is large by nature is erroneously determined to be a contact instance in accordance with an excessively small threshold value.

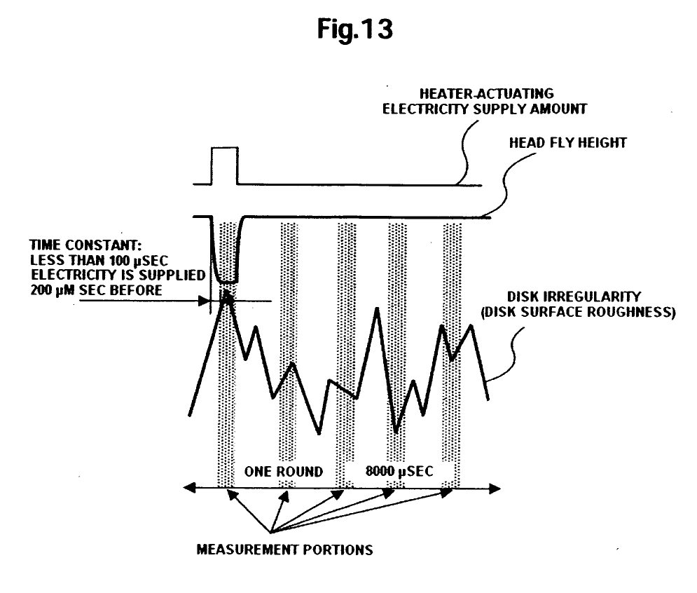

Technical measures regarding electricity-supply time periods are shown in FIG. 13. More specifically, FIG. 13 shows a case where measurement is carried out at five circumferential positions. For contact measurement, it is not necessary to maintain a low fly state by all time electricity supply for one lap or round. When the structure of the heater 5c is appropriately set, time period necessary for displacement to reach a portion with a remaining portion corresponding to 1/e times with respect to the time constant, that is, full stroke, can be regulated to substantially 100 μsec. In this case, e is the base or bottom of the natural logarithm. As such, it is preferable to perform electricity supply for a minimum necessary time period and not long so as to not induce wear of the magnetic head slider. Further, after passage through an electricity supply portion, it is desirable that electricity supply be quickly stopped. In the present embodiment, electricity supply is started 200 μsec before the respective measurement portion, and is quickly stopped at a portion past the measurement portion. When electricity supply is started 100 μsec or more to 100 μsec or less before the respective measurement portion, heating by the heater 5c can be sufficiently accomplished.

What is claimed is:

1. A manufacturing method for a magnetic disk drive, characterized by comprising the steps of:
assembling into a housing a spindle motor to which a magnetic disk medium is mounted and a magnetic head slider including recording/playback elements and a heater, the recording/playback elements configured to perform recording/playback of magnetic information on the magnetic disk medium by flying close to thereto, and the heater configured to regulate a fly height and disposed in the vicinity of the recording/playback elements;
playing back magnetic information on a specific track of the magnetic disk medium by using the recording/playback elements while gradually increasing an electricity supply amount for the heater;
measuring an amplitude of a playback signal in the step of playing back at a plurality of portions along a circumferential direction of the track;
detecting contact between the magnetic head slider and the magnetic disk medium in accordance with an increase in variation in the measured amplitude; and
setting an appropriate electricity supply amount for the magnetic head slider, wherein the value being obtained by subtracting an predetermined value of an electricity supply amount from an electricity supply amount in the event of detection of the contact is set as the appropriate electricity supply amount.

2. The manufacturing method for a magnetic disk drive in accordance with claim 1, wherein:
the amplitude of the playback signal in the respective measurement portion is a value obtained by subtracting a reference from a value measured in a state where, the electricity supply amount for the heater, the reference value having been measured in a state where an electricity supply amount for the heater is sufficiently small and hence the magnetic head slider and the magnetic disk medium are not in contact with one another.

3. The manufacturing method for a magnetic disk drive in accordance with claim 2, wherein:
the amplitude of the playback signal measured at the respective portion is evaluated for variation after being normalized by being divided by an average value of values at all the portions.

4. The manufacturing method for a magnetic disk drive in accordance with claim 1, wherein:
the amplitude of the playback signal measured at the respective portion is evaluated for variation after being normalized by being divided by an average value of values at all the portions.

5. The manufacturing method for a magnetic disk drive in accordance with claim 1, wherein:
in the step of measuring the amplitude of the playback signal, a distance between each of the plurality of portions for measurement is non-constant or variable, and a minimum alteration unit thereof is smaller than a distance obtained by dividing a peripheral speed of the magnetic disk medium by 300 kHz.

6. The manufacturing method for a magnetic disk drive in accordance with claim 1, wherein:
in the step of measuring the amplitude of the playback signal, a distance between each of the plurality of portions for measurement is non-constant or random, and a minimum alteration unit thereof is smaller than a distance obtained by dividing a peripheral speed of the magnetic disk medium by 300 kHz.

7. The manufacturing method for a magnetic disk drive in accordance with claim 1, wherein:
as a parameter indicative of the amplitude of the playback signal, a gain regulation parameter (gain of variable gain amplifier) is used.

8. The manufacturing method for a magnetic disk drive in accordance with claim 1, the method being characterized in that the step of playing back magnetic information, the step of measuring an amplitude of a playback signal, the step of detecting contact between the magnetic head slider and the magnetic disk medium, and the step of setting an appropriate electricity supply amount for the magnetic head slider are executed on a plurality of tracks in different radial positions.

9. The manufacturing method for a magnetic disk drive in accordance with claim 8, wherein:
the detection of contact between the magnetic head slider and the magnetic disk medium is executed by using a threshold value set corresponding to respective one of the plurality of tracks.

10. The manufacturing method for a magnetic disk drive in accordance with claim 1, wherein:
the step of playing back magnetic information, the step of measuring an amplitude of a playback signal, the step of detecting contact between the magnetic head slider and the magnetic disk medium, and the step of setting an appropriate electricity supply amount for the magnetic head slider are executed on tracks in an inner circumference portion, inbetween circumference portion, and outer circumference portion of the magnetic disk medium.

11. The manufacturing method for a magnetic disk drive in accordance with claim 1, wherein:
the step of setting an appropriate electricity supply amount for the magnetic head slider is a step of setting the appropriate electricity supply amount correspondingly to an environmental temperature and separately for a recording operation and a playback operation.

12. A manufacturing method for a magnetic disk drive, comprising the steps of:
assembling into a housing a spindle motor to which a magnetic disk medium is mounted and a magnetic head slider including recording/playback elements and a heater, the recording/playback elements being for performing recording/playback of magnetic information on the magnetic disk medium by flying close to thereto, and the heater being for regulating a fly height and disposed in the vicinity of the recording/playback elements;
playing back magnetic information on a specific track of the magnetic disk medium by using the recording/playback elements while gradually increasing an electricity supply amount for supply to the heater;
measuring plural times an amplitude of a playback signal in the step of playing back at a same portion of the track;
detecting contact between the magnetic head slider and the magnetic disk medium in accordance with an increase in variation in the measured amplitude; and
setting an appropriate electricity supply amount for the magnetic head slider, wherein the value being obtained by subtracting an predetermined value of an electricity supply amount from an electricity supply amount in the event of detection of the contact is set as the appropriate electricity supply amount.

13. The manufacturing method for a magnetic disk drive in accordance with claim 12, wherein the step of playing back magnetic information, the step of measuring plural times an amplitude of a playback signal, and the step of detecting contact between the magnetic head slider and the magnetic disk medium are executed on a plurality of circumferential portions of the track.

14. The manufacturing method for a magnetic disk drive in accordance with claim 13, wherein:
the detection of contact between the magnetic head slider and the magnetic disk medium is executed by using a threshold value set corresponding to respective one of the plurality of circumferential portions.

15. The manufacturing method for a magnetic disk drive in accordance with claim 12, wherein:
as a parameter indicative of the amplitude of the playback signal, a gain regulation parameter (gain of variable gain amplifier) is used.

16. The manufacturing method for a magnetic disk drive in accordance with claim 12, wherein:
electricity supply to the heater is started before the measurement portion and stopped at a t6ime point after passage through the measurement portion.

17. The manufacturing method for a magnetic disk drive in accordance with claim 16, wherein:
electricity supply to the heater is started 100 microseconds or more to 1000 microseconds or less before the measurement portion.

18. The manufacturing method for a magnetic disk drive in accordance with claim 12, wherein the step of playing back magnetic information, the step of measuring an amplitude of a playback signal, the step of detecting contact between the magnetic head slider and the magnetic disk medium, and the step of setting an appropriate electricity supply amount for the magnetic head slider are executed on tracks in an inner circumference portion, inbetween circumference portion, and outer circumference portion of the magnetic disk medium.

19. The manufacturing method for a magnetic disk drive in accordance with claim 12, wherein:
the step of setting an appropriate electricity supply amount for the magnetic head slider is a step of setting the appropriate electricity supply amount correspondingly to an environmental temperature and separately for a recording operation and a playback operation.
